(19) United States
(12) Patent Application Publication
(10) Pub. No.: US 2026/0305020 A1
(43) Pub. Date: Oct. 1, 2026

(54) SEMICONDUCTOR DEVICE

(71) Applicant: EPISTAR CORPORATION, Hsinchu (TW)

(72) Inventors: Hui-Fang Kao, Hsinchu (TW); Ching-Hsing Shen, Hsinchu (TW); Hsiang-Fa Wu, Hsinchu (TW); Meng-Fang Wu, Hsinchu (TW)

(21) Appl. No.: 19/097,015

(22) Filed: Apr. 1, 2025

(51) Int. Cl. H10H 20/816; H10H 20/831

(52) U.S. Cl. CPC H10H 20/816; H10H 20/831

(57) ABSTRACT

A semiconductor device is provided, which has a first long side and a second long side opposite to the first long side. The semiconductor device includes a semiconductor stack, a first lower contact structure, a first mesa contact structure, and a first electrode structure. The semiconductor stack has a lower portion and a mesa portion connected to the lower portion. The first lower contact structure is on the lower portion. The first mesa contact structure is on the mesa portion and includes a first injection part, a first extension part connected to the first injection part, a second injection part separated from the first extension part, and a second extension part connected to the second injection part. The first electrode structure covers a part of the mesa portion and is electrically connected to the first mesa contact structure.

### BACKGROUND OF THE INVENTION

### Field of the Invention

The present disclosure relates to semiconductor devices, and, in particular, to a semiconductor device with a contact structure including two injection parts and two extension parts.

### Description of the Related Art

In semiconductor devices, current is usually injected into the first contact on the p-semiconductor structure and the second contact on the n-semiconductor structure to drive active regions in the semiconductor device to work (e.g., emitting light). However, as the aspect ratio of the semiconductor device increases, the length of the first contact and the second contact increases, thereby increasing the transmission distance of the current. In this case, an excessively long transmission distance may cause the semiconductor device to have undesirable optoelectronic properties (e.g., emitting light un-uniformly). Therefore, although existing semiconductor devices have largely met their intended purposes, they do not meet requirements in all respects. Therefore, there is still a need to improve semiconductor devices.

### BRIEF SUMMARY OF THE INVENTION

In some embodiments, a semiconductor device is provided, which has a first long side and a second long side opposite to the first long side. The semiconductor device includes a semiconductor stack, a first lower contact structure, a first mesa contact structure, and a first electrode structure. The semiconductor stack has a lower portion and a mesa portion connected to the lower portion. The first lower contact structure is on the lower portion. The first mesa contact structure is on the mesa portion and includes a first injection part, a first extension part connected to the first injection part, a second injection part separated from the first extension part, and a second extension part connected to the second injection part. The first electrode structure covering a part of the mesa portion and electrically connected to the first mesa contact structure.

In some embodiments, a semiconductor device is provided. The semiconductor device includes a semiconductor stack, a first lower contact structure, a first mesa contact structure, and a first electrode structure. The semiconductor stack has a lower portion and a mesa portion connected to the lower portion. The first lower contact structure is on the lower portion and includes a first injection part, a first extension part connected to the first injection part, a second injection part separated from the first extension part, and a second extension part connected to the second injection part. The first mesa contact structure is on the mesa portion. The first electrode structure covering a part of the mesa portion and electrically connected to the first mesa contact structure.

The device of the present disclosure can be applied in a variety of electronic devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view showing the semiconductor device according to some embodiments of the present disclosure.

FIG. 2 is a cross-sectional view showing the semiconductor device along line A-A′ of FIG. 1.

FIG. 3A is an enlarged diagram showing a portion of the semiconductor device of FIG. 1.

FIG. 3B is a cross-sectional view showing the semiconductor device along line B-B′ of FIG. 3B.

FIG. 3C is an enlarged diagram showing a portion of the semiconductor device of FIG. 1.

FIG. 3D is a cross-sectional view showing the semiconductor device along line C-C′ of FIG. 3C.

FIG. 4 is a top view showing the semiconductor device according to some embodiments of the present disclosure.

FIG. 5 is a top view showing the semiconductor device according to some embodiments of the present disclosure.

FIG. 6A is a top view showing the semiconductor device according to some embodiments of the present disclosure.

FIG. 6B is a top view showing the semiconductor device according to some embodiments of the present disclosure.

FIG. 7 is a top view showing the semiconductor device according to some embodiments of the present disclosure.

### DETAILED DESCRIPTION OF THE INVENTION

The devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

In some embodiments of the present disclosure, the terms related to bonding and connection can also include embodiments in which both structures are movable, or both structures are fixed.

In addition, the ordinal numbers such as “first”, “second”, “third”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name.

For clarity of explanation, some features of the devices are omitted in the drawings, and only some features are schematically illustrated. In some embodiments, additional features may be added to the devices described below. In some other embodiments, features in several different embodiments may be replaced or omitted. It should be understood that in some embodiments, additional operational steps may be provided before, during, and/or after the method of forming the devices. In some embodiments, some of the steps described may be replaced or omitted, and the order of some of the steps described is interchangeable.

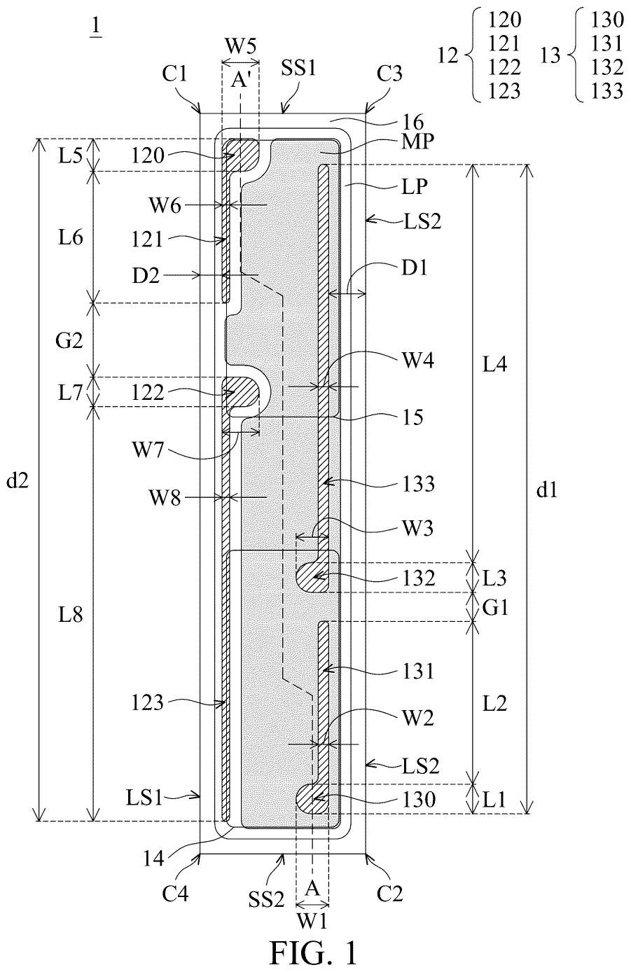

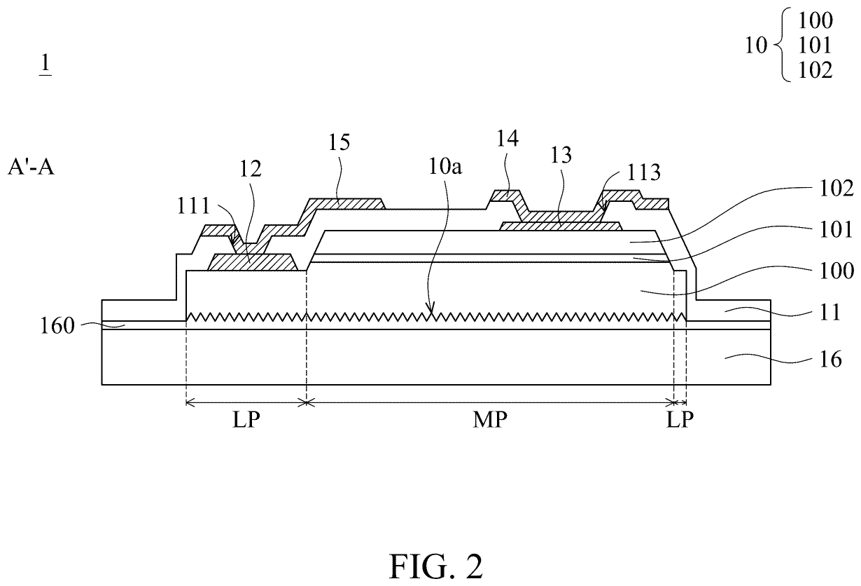

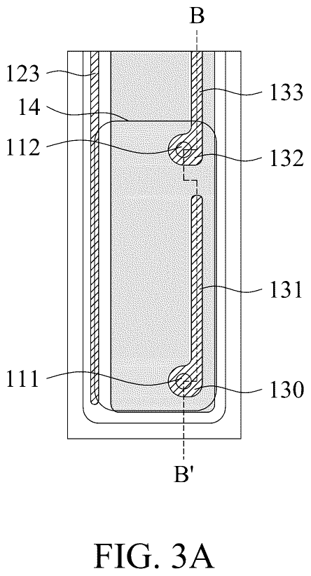

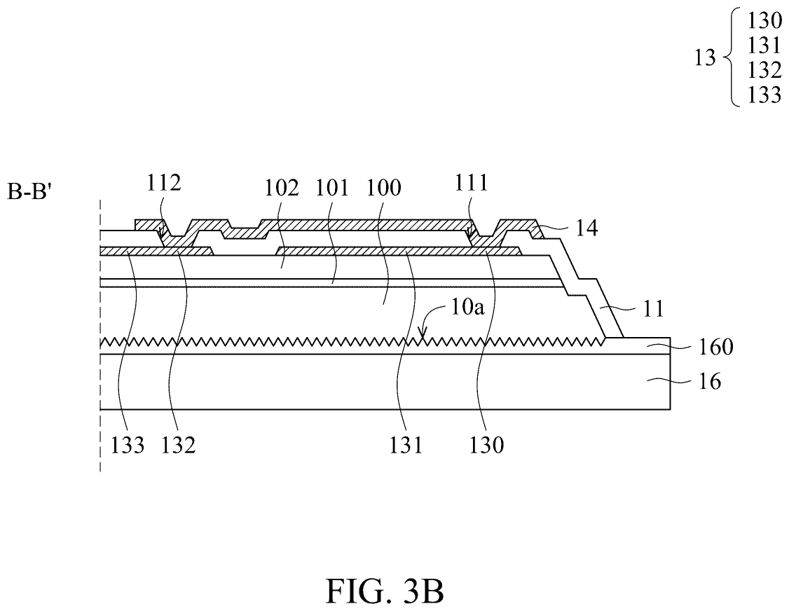

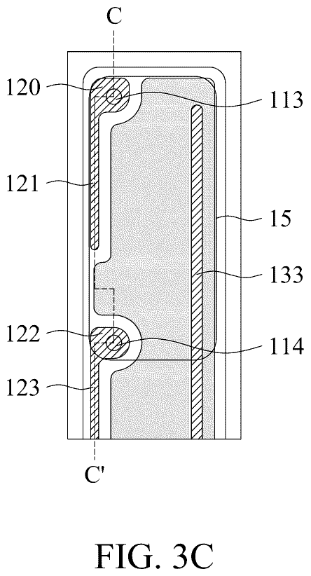

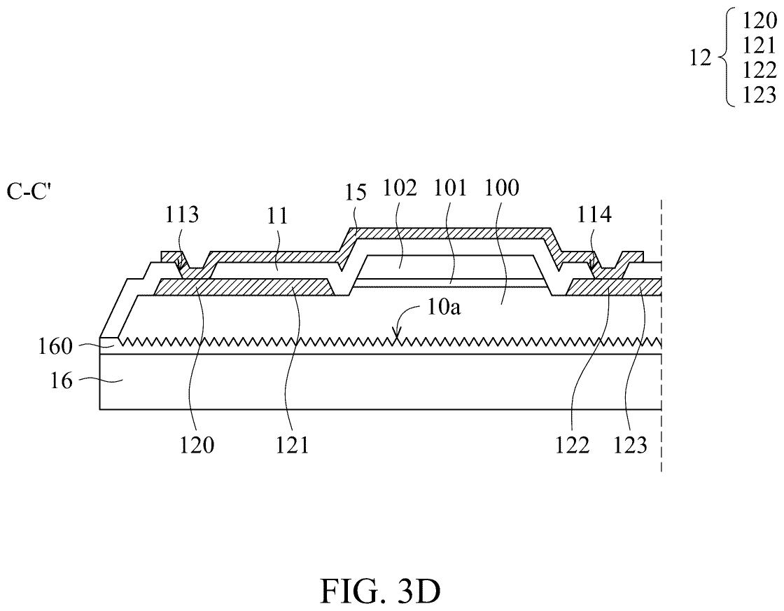

FIG. 1 is a top view showing the semiconductor device 1 according to some embodiments of the present disclosure. FIG. 2 is a cross-sectional view showing the semiconductor device 1 along line A-A′ of FIG. 1. For the sake of simplicity, some structures are omitted from FIG. 1. FIG. 3A is an enlarged diagram showing a portion of the semiconductor device 1 of FIG. 1. FIG. 3B is a cross-sectional view showing the semiconductor device 1 along line B-B′ of FIG. 3B. FIG. 3C is an enlarged diagram showing a portion of the semiconductor device 1 of FIG. 1. FIG. 3D is a cross-sectional view showing the semiconductor device 1 along line C-C′ of FIG. 3C.

As shown in FIG. 1, from a top view, the semiconductor device 1 includes a first long side LS1, a second long side LS2 opposite to the first long side LS1, a first short side SS1 between the first long side LS1 and the second long side LS2, and a second short side SS2 opposite to the first short side SS1. In the embodiment, the shape of the semiconductor device 1 is a rectangle. In addition, the semiconductor device 1 has a first corner C1 formed by the first long side LS1 and the first short side SS1, and has a second corner C2 formed by the second long side LS2 and the second short side SS2. The first corner C1 and the second corner C2 are not adjacent to each other in the horizontal and vertical directions. Furthermore, the semiconductor device 1 also has a third corner C3 formed by the second long side LS2 and the first short side SS1, and also has a fourth corner C4 formed by the first long side LS1 and the second short side SS2.

As shown in FIG. 2, from a cross-sectional view, the semiconductor device 1 includes a semiconductor stack 10, an insulating structure 11, a first electrode structure 14, and a second electrode structure 15. The semiconductor device 1 optionally includes a first lower contact structure 12 and/or a first mesa contact structure 13. The semiconductor stack 10 includes a first semiconductor structure 100, an active region 101, and a second semiconductor structure 102 stacked in sequence. In some embodiments, the first semiconductor structure 100 has a first conductivity type, and the second semiconductor structure 102 has a second conductivity type different from the first conductivity type. For example, the first semiconductor structure 100 is n-type and the second semiconductor structure 102 is p-type. Alternatively, the first semiconductor structure 100 is p-type and the second semiconductor structure 102 is n-type. Therefore, the first semiconductor structure 100 and the second semiconductor structure 102 may respectively provide electrons and holes, or provide holes and electrons.

In the present disclosure, the semiconductor stack 10 includes a lower portion LP and a mesa portion MP connected to the lower portion LP. The lower portion LP includes a part of the first semiconductor structure 100, and the mesa portion MP includes the other part of the first semiconductor structure 100, the active region 101, and the second semiconductor structure 102.

As shown in FIG. 2, the first mesa contact structure 13 is disposed on the mesa portion MP and in contact with the second semiconductor structure 102 of the mesa portion MP. More specially, the first mesa contact structure 13 locates between the second semiconductor structure 102 and the first electrode structure 14. In addition, as shown in FIG. 1, the first mesa contact structure 13 is close to the second long side LS2 and away from the first long side LS1.

In these embodiments of FIG. 1, the first mesa contact structure 13 includes a first injection part 130, a first extension part 131 connected to the first injection part 130, a second injection part 132 separated from the first extension part 131, and a second extension part 133 connected to the second injection part 132.

The first extension part 131 separates from the second injection part 132 by a first gap G1. By virtue of including the two injection parts 130, 132 and/to two extension parts 131, 133, the transmission distance of the current can be significantly decreased, and the luminous intensity of the active region below the end of the extension parts (the position away from the injection part) can be also improved.

In some embodiments, the first injection part 130 locates near the second corner C2, and the first injection part 130, the first extension part 131, the second injection part 132, and the second extension part 133 are arranged along the second long side LS2 from the second short side SS2 toward the first short side SS1.

In some embodiments, the first extension part 131 and/or the second extension part 133 are substantially parallel to the first long side LS1. In some embodiments, the first extension part 131 and/or the second extension part 133 may have an included angle such as 0.1° to 5° with the first long side LS1. In some embodiments, the first extension part 131 may have an included angle such as 0.1° to 5° with the second extension part 133.

In some embodiments, the first injection part 130 includes a first width W1, and the first extension part 131 includes a second width W2 less than the first width W1. In the present disclosure, the first width W1 and the second width W2 are parallel to the first short side SS1. The insulating structure 11 does not cover the injection parts 130, 132 which are used to be connected to the electrode structure 14, 15, and the insulating structure 11 covers the extension parts 131, 133 which are used as a transmission path of a current. Since the injection part 130, 132 having a wider width is used for connecting to the electrode structure 14, 15, the electrical connection between the contact structure and the electrode structure 14, 15 thereon is improved. Similarly, in some embodiments, the second injection part 132 includes a third width W3, and the second extension part 133 includes a fourth width W4 less than the third width W3. In some embodiments, the first width W1 is the same as the third width W3, and/or the second width W2 is the same as the fourth width W4.

In some embodiments, the first injection part 130 includes a first length L1, and the first extension part 131 includes a second length L2 greater than the first length L1. In the present disclosure, the first length L1 and the second length L2 are parallel to the first long side LS1. In some embodiments, the second injection part 132 includes a third length L3, and the second extension part 133 includes a fourth length L4 greater than the third length L3. In some embodiments, the first length L1 is the same as the third length L3, and/or the second length L2 is less than the fourth length L4. In some embodiments, the sum of the fourth length L4 and the third length L3 is greater than the sum of the second length L2 and the first length L1.

As shown in FIG. 2, the first lower contact structure 12 is disposed on the lower portion LP and in contact with the first semiconductor structure 100 of the lower portion LP. More specifically, the first lower contact structure 12 locates between the first semiconductor structure 100 and the second electrode structure 15. In addition, as shown in FIG. 1, the first lower contact structure 12 is close to the first long side LS1 and away from the second long side LS2. The first lower contact structure 12 includes a third injection part 120, a third extension part 121 connected to the third injection part 120, a fourth injection part 122 separated from the third extension part 121, and a fourth extension part 123 connected to the fourth injection part 122. That is, the first lower contact structure 12 includes two injection parts and two sections of extension part. Similarly, by virtue of including the two injection parts 120, 122 and/to two extension parts 121, 123, the transmission distance of the current can be significantly decreased, thereby improving the luminous intensity of the active region below the end of the extension part (the position away from the injection part).

In some embodiments, the third injection part 120 locates near the first corner C1, and the third injection part 120, the third extension part 121, the fourth injection part 122, and the fourth extension part 123 are arranged along the first long side LS1 from the first short side SS1 toward the second short side SS2. In some embodiments, the third extension part 121 and/or the fourth extension part 123 are substantially parallel to the first long side LS1. In some embodiments, the third extension part 121 and/or the fourth extension part 123 may have an included angle such as 1° to 5° with the first long side LS1. In some embodiments, the third extension part 121 may have an included angle such as 1° to 5° with the fourth extension part 123.

In some embodiments, the first injection part 130 and the first extension part 131 correspond to (e.g., be adjacent to or be side by side) the fourth injection part 122 and the fourth extension part 123. In some embodiments, the second injection part 132 and the second extension part 133 correspond to (e.g., be adjacent to or be side by side) the third injection part 120 and the third extension part 121.

In some embodiments, the third injection part 120 includes a fifth width W5, and the third extension part 121 includes a sixth width W6 less than the fifth width W5. In some embodiments, the fourth injection part 122 includes a seventh width W7, and the fourth extension part 123 includes an eighth width W8 less than the seventh width W7. In some embodiments, the fifth width W5 is the same as the seventh width W7, the sixth width W6 is the same as the eighth width W8, and/or the second width W2 is the same as the fourth width W4.

In some embodiments, the third injection part 120 includes a fifth length L5, and the third extension part 121 includes a sixth length L6 greater than the fifth length L5. In some embodiments, the fourth injection part 122 includes a seventh length L7, and the fourth extension part 123 includes an eighth length L8 greater than the seventh length L7. In some embodiments, the fifth length L5 is the same as the seventh length L7, and/or the sixth length L6 is less than the eighth length L8. In some embodiments, the sum of the fifth length L5 and the sixth length L6 is less than the sum of the seventh length L7 and the eighth length L8.

In some embodiments, the size (e.g., length or width) of the third injection part 120, the fourth injection part 122, the first injection part 130, and the second injection part 132 may be the same. In some embodiments, each of the second width W2 and the fourth width W4 are larger than each of the sixth width W6 and the eighth width W8. In some embodiments, the gap G1 between the first extension part 131 and the second injection part 132 is less than the gap G2 between the third extension part 121 and the fourth injection part 122. In other embodiments, the gap G1 is the same as or larger than the gap G2.

In some embodiments, a first distance D1 between the first mesa contact structure 13 and the second long side LS2 is less than a second distance D2 between the first lower contact structure 12 and the first long side LS1. In some embodiments, a first longest distance d1 between the first injection part 130 and the second extension part 133 is less than a second longest distance d2 between the third injection part 120 and the fourth extension part 123. In other embodiments, the second longest distance d2 is smaller than or same as the first longest distance d1.

As shown in FIG. 2, the insulating structure 11 covers the semiconductor stack 10 the first mesa contact structure 13 and the first lower contact structure 12. The insulating structure 11 includes a first opening 111 to expose the first injection part 130 and a second opening 112 (shown in FIGS. 3A-3B) to expose the second injection part 132. The insulating structure 11 further includes a third opening 113 to expose the third injection part 120 and a fourth opening 114 (shown in FIGS. 3C-3D) to expose the fourth injection part 122. More specially, the insulating structure 11 covers the first semiconductor structure 100, the second semiconductor structure 102, a part of the first mesa contact structure 13 (i.e., the first extension part 131 and the second extension part 133), and a part of the first lower contact structure 12 (i.e., the third extension part 121 and the fourth extension part 123) to prevent the unex-pected electrical connection and protect the elements.

As shown in FIGS. 2 and 3A-3B, the first electrode structure 14 is electrically connected to the first mesa contact structure 13. The first electrode structure 14 covers a part of the mesa portion MP, a part of the lower portion LP, the first injection part 130, the first extension part 131, the second injection part 132 and a part of the second extension part 133. More specifically, the first electrode structure 14 is in contact with the first injection part 130 and the second injection part 132 through the first opening 111 and the second opening 112. In some embodiments, the first electrode structure 14 is conformally disposed on the first mesa contact structure 13 and the insulating structure 11.

As shown in FIGS. 2 and 3C-3D, the second electrode structure 15 is electrically connected to the first lower contact structure 12. The second electrode structure 15 covers a part of the mesa portion MP, a part of the lower portion LP, the third injection part 120, the third extension part 121, the fourth injection part 122, and a part of the fourth extension part 123. More specifically, the second electrode structure 15 is in contact with the third injection part 120 and the fourth injection part 122 through the third opening 113 and the fourth opening 114. In some embodiments, the second electrode structure 15 is conformally disposed on the first lower contact structure 12 and the insulating structure 11.

In some embodiments, the semiconductor device 1 further optionally includes a base 16 and/or an adhesive layer 160 between the semiconductor stack 10 and the base 16. In some embodiments, the base 16 may be a growth substrate for the semiconductor stack 10. In some embodiments, the base 16 may be omitted. In some embodiments, the base 16 may be a single layer or a stack of multiple layers. In some embodiments, the semiconductor stack 10 has a bottom surface 10a facing the base 16, and the bottom surface 10a is a roughing surface. In this embodiment, since the semiconductor stack 10 is grown on another growth wafer, and then the semiconductor stack 10 is bonded to the base 16 through the adhesive layer 160 using the semiconductor wafer slicing technology, the bottom surface 10a of the semiconductor stack 10 has larger roughness helps to increase the mechanical strength after bonding, and can increase the light direction efficiency.

In some embodiments, the first semiconductor structure 100, the active region 101, and the second semiconductor structure 102 may include III-V semiconductor materials, such as aluminum (Al), gallium (Ga), arsenic (As), phosphorus (P), or indium (In). For example, the III-V semiconductor material may be a binary compound semiconductor (such as GaAs, GaP, GaN, or InP), a ternary compound semiconductor (such as InGaAs, AlGaAs, GaInP, AlInP, InGaN, or AlGaN), or a quaternary compound semiconductor (such as AlGaInAs, AlGaInP, AlInGaN, InGaAsP, InGaAsN, or AlGaAsP).

In some embodiments, the semiconductor stack 10 may be formed on the base 16 through epitaxial process. The epitaxy process may include metal-organic chemical vapor deposition (MOCVD), molecular beam epitaxy (MBE), liquid phase epitaxy (LPE), vapor phase epitaxy (VPE), or a combination thereof.

In some embodiments, a doping process may be performed on the first semiconductor structure 100 and the second semiconductor structure 102, so that the first semiconductor structure 100 includes a first dopant and thus has a first conductivity type, and the second semiconductor structure 102 includes a second dopant and thus has a second conductivity type. For example, the doping process may include in-situ doping during epitaxial growth, implanting after epitaxial growth, or a combination thereof. In some embodiments, the first dopant or the second dopant may be magnesium (Mg), zinc (Zn), silicon (Si), carbon (C), or tellurium (Te).

In some embodiments, the active region 101 may emit light, and the light emitted by the active region 101 may include visible light or invisible light. The wavelength of the light emitted by the active region 101 depends on the material composition of the active region 101. For example, when the material of the active region 101 is or includes the InGaN series, the active region 101 may emit blue light or deep blue light with a peak wavelength of 400 nm to 490 nm, green light with a peak wavelength of 490 nm to 550 nm, or red light with a peak wavelength of 560 nm to 650 nm. When the material of the active region 101 is or includes the AlGaN series, the active region 101 may emit ultraviolet light with a peak wavelength of 250 nm to 400 nm. When the material of the active region 101 is or includes the InGaAs series, InGaAsP series, AlGaAs series, or AlGaInAs series, the active region 101 may emit infrared light with a peak wavelength of 700 nm to 1700 nm. When the material of the active region 101 is or includes InGaP series or AlGaInP series, the active region 101 may emit red light with a peak wavelength of 610 nm to 700 nm, or yellow light with a peak wavelength of 530 nm to 600 nm.

In some embodiments, the insulating structure 11 may include a single layer or a multi-layer stack of dielectric materials. For example, the dielectric material may include oxides, nitrides, polymer materials, a combination thereof, or other suitable dielectric materials, such as silicon dioxide (SiO₂), silicon nitride (SiₓN_{y}), etc. In some embodiments, the insulating structure 11 has a reflectivity higher than 80% for the light emitted by the active region 101. For example, the reflectivity is 85% to 100%. In some embodiments, the insulating structure 11 may include distributed Bragg reflector (DBR).

In some embodiments, the first mesa contact structure 13, the first lower contact structure 12, the first electrode structure 14, or the second electrode structure 15 may include conductive material. For example, the conductive material may include metals, metal compounds, or a combination thereof. In some embodiments, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), germanium (Ge), beryllium (Be), or alloys thereof. In some embodiments, the metal compound may be tantalum nitride (TaN), titanium nitride (TiN), tungsten silicide (WSi₂), indium tin oxide (ITO), indium oxide (InO), tin oxide (SnO), Cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium oxide Zinc (IZO), or indium gallium zinc oxide (IGZO), etc. In some embodiments, the material of any two of the first mesa contact structure 13, the first lower contact structure 12, the first electrode structure 14, and the second electrode structure 15 may be the same or different.

In some embodiments, the first mesa contact structure 13, the first lower contact structure 12, the first electrode structure 14, or the second electrode structure 15 may be formed by an electroplating process, a physical vapor deposition process (e.g., a sputtering process), a chemical vapor deposition process, a combination thereof, or other suitable processes. In some embodiments, any two of the first mesa contact structure 13, the first lower contact structure 12, the first electrode structure 14, and the second electrode structure 15 may be formed by different processes.

In some embodiments, the base 16 may include silicon (Si), diamond (C), silicon carbide (SiC), sapphire, glass, gallium oxide (Ga₂O₃), gallium nitride (GaN), aluminum gallium nitride (AlGaN), aluminum nitride (AlN), gallium phosphide (GaP), gallium arsenide (GaAs), aluminum gallium arsenide (AlGaAs), or a combination thereof. For example, the base 16 may include silicon carbide, sapphire, or gallium nitride. In some embodiment, the base 16 has a high transmittance for the light emitted by the active region 101. For example, the base 16 is made of a transparent material, and the transmittance of the light emitted by the active region 101 is higher than 85%.

The adhesive layer 160 connects the base 16 and the semiconductor stack 10. In one embodiment, the adhesive layer 160 can be a single layer or multiple layers (not shown). The material of the adhesive layer 160 may include transparent insulating materials. The transparent insulating materials include but are not limited to titanium oxide (TiO₂), niobium oxide (Nb₂O₅), silicon oxide (SiO₂), aluminum oxide (Al₂O₃), silicon nitride (SiN) or BCB.

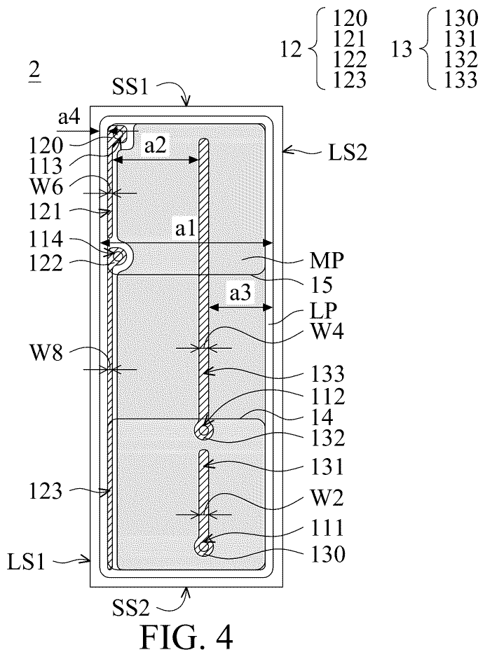

FIG. 4 is a top view showing the semiconductor device 2 according to some embodiments of the present disclosure. More specifically, the semiconductor device 2 of FIG. 4 is similar to the semiconductor device of FIG. 1, the differences between them are the following. In some embodiments, the shape of the third injection part 120 is different from the shape of the first injection part 130. The shape of the fourth injection part 122 is different from the shape of the second injection part 132. For example, the shapes of the third injection part 120 and the fourth injection part 122 are approximately rectangle. In addition, the third extension part 121 includes a central axis not passed through a center of the third injection part 120. The fourth extension part 123 includes a central axis not passed through a center of the fourth injection part 122. On the contrary, the shapes of the first injection part 130 and the second injection part 132 are circle. In addition, the first extension part 131 includes a central axis passing through a center of the first injection part 130, the second extension part 133 includes a central axis passing through a center of the second injection part 132.

As shown in FIG. 4, the semiconductor stack 10 has a width a1. There is a first shortest distance a2 between the first mesa contact structure 13 and the first lower contact structure 12, and there is a second shortest distance a3 between the first mesa contact structure 13 and a side of the semiconductor stack 10 close to the second long side LS2. Besides, there is a third shortest distance a4 between the first lower contact structure 12 and a side of the semiconductor stack 10 close to the first long side LS1. In some embodiments, the first shortest distance a2 is greater than the second shortest distance a3. In some embodiments, the second shortest distance a3 is same as or different from the third shortest distance a4. For example, the second shortest distance a3 is less than or greater than the third shortest distance a4. In some embodiments, a ratio of the first shortest distance a2 and the width a1 (i.e., a2/a1) is 0.35 to 0.75, such as 0.4, 0.5, 0.6, 0.7. In some embodiments, a ratio of the second shortest distance a3 and the width a1 (i.e., a3/a1) is 0.1 to 0.5, such as 0.2, 0.3, 0.4. In some embodiments, a ratio of the first shortest distance a2 and the second shortest distance a3 (i.e., a2/a3) is 0.7 to 7.5, such as 1, 3, 5, 7.

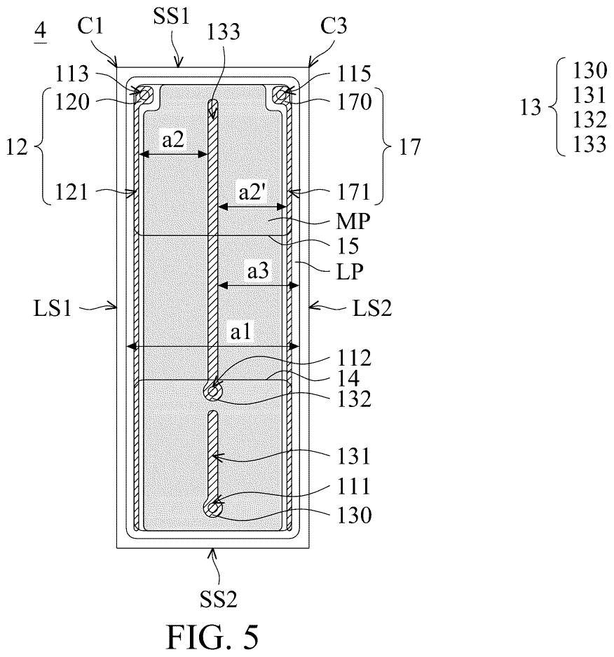

FIG. 5 is a top view showing the semiconductor device 4 according to some embodiments of the present disclosure. Compared to the semiconductor device 3 of FIG. 4, the semiconductor device of FIG. 5 further includes a second lower contact structure 17 parallel to the first long side LS1. The second lower contact structure 17 is on the lower portion LP, and the second lower contact structure 17 is close to the second long side LS2 and away from the first long side LS1. In other words, the mesa portion MP and the first mesa contact structure 13 are between the first lower contact structure 12 and the second lower contact structure 17 from the top view of the semiconductor device. By providing the first lower contact structure 12 and the second lower contact structure 17 near the two long sides (such as the first long side LS1 and the second long side LS2) of the semiconductor device 4, the opto-electronic properties (such as near-field uniformity) may be further improved.

In some embodiments, the first lower contact structure 12 includes the third injection part 120 and the third extension part 121 connected to the third injection part 120, and the second lower contact structure 17 includes the fifth injection part 170 and the fifth extension part 171 connected to the fifth injection part 170. In some embodiments, the third injection part 120 of the first lower contact structure 12 and the fifth injection part 170 of the second lower contact structure 17 are at the corners of the semiconductor device 4 that are adjacent to each other. For example, the third injection part 120 and the fifth injection part 170 are at the first corner C1 and the third corner C3, respectively.

In some embodiments, the first lower contact structure 12 are the second lower contact structure 17 symmetrical with respect to the first mesa contact structure 13. In some embodiments, the first lower contact structure 12 is symmetrical with the second lower contact structure 17 with respect to a center axis of the semiconductor device 4. In some embodiments, the shape, the size (such as length or width), and/or the material of the first lower contact structure 12 and the second lower contact structure 17 are the same or similar.

As shown in FIG. 5, the semiconductor stack 10 has a width a1. There is a first shortest distance a2 between the first mesa contact structure 13 and the first lower contact structure 12, and there is a fourth shortest distance a2′ between the first mesa contact structure 13 and the second lower contact structure 17. Besides, there is a second shortest distance a3 between the first mesa contact structure 13 and a side of the semiconductor stack 10 close to the second long side LS2. In some embodiments, the distance a2 is the same as the distance a2′. In some embodiments shown in FIG. 4, the ratio of the second shortest distance a3 and the width a1 (i.e., a3/a1) is 0.3-0.5, which is greater than or equal to the ratio of the second shortest distance a3 and the width a1 (i.e., a3/a1) shown in FIG. 4.

In some embodiments, the second lower contact structure 17 of FIG. 5 may be similar to the first lower contact structure 12 of FIG. 1. That is, the first lower contact structure 12 of FIG. 4 may include the third injection part 120, the third extension part 121 connected to the third injection part 120. Similarly, the second lower contact structure 17 may include a fifth injection part 170, a fifth extension part 171 connected to the fifth injection part 170. Among them, the third extension part 121 and/or the fifth extension part 171 are parallel to the first long side LS1 and the second long side LS2. In other embodiments, the first lower contact structure 12 further includes a fourth injection part (referring to FIG. 1) separated from the third extension part 121, and the fourth extension part (referring FIG. 1) connected to the fourth injection part. In some embodiments, the second lower contact structure 17 can further includes a sixth injection part (similar to the fourth injection part) separated from the fifth extension part 171, and a sixth extension part (similar to the fourth extension part) connected to the sixth injection part.

Similar to the semiconductor device 1 shown in FIGS. 3A-3B, the semiconductor device 4 in FIG. 5 also includes an insulating structure 11 having a first opening 111 to expose the first injection part 130, a second opening 112 to expose the second injection part 132, and a third opening 113 to expose the third injection part 120. Besides, the insulating structure 11 also includes fifth opening 115 to expose the fifth injection part 170. The first extension part 131, the second injection part 133, the third extension part 121, the fifth extension part 171 are covered by the insulating structure 11.

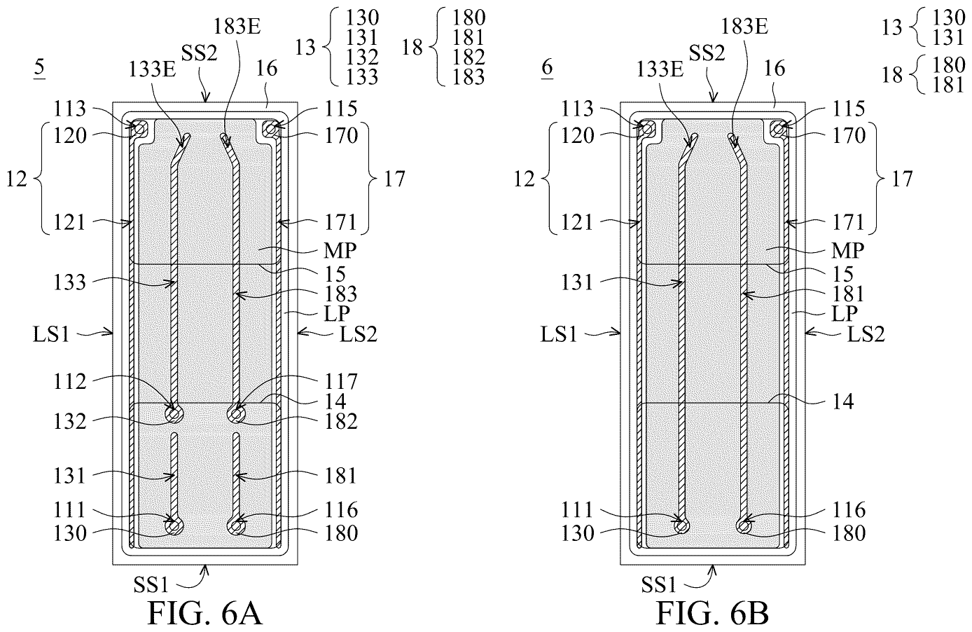

FIG. 6A is a top view showing the semiconductor device 5 according to some embodiments of the present disclosure. Compared to the semiconductor device 4 of FIG. 5, the semiconductor device 5 of FIG. 6A further includes second mesa contact structure 18 located on the mesa portion MP. The first mesa contact structure 13 and the second mesa contact structure 18 are between the first lower contact structure 12 and the second lower contact structure 17. The first mesa contact structure 13 is close to the first long side LS1 and away from the second long side LS2, and the second mesa contact structure 18 is close to the second long side LS2 and away from the first long side LS1. By providing two mesa contact structures (the first mesa contact structure 13 and the second mesa contact structure 18), the optoelectronic properties (such as near-field uniformity) may be further improved.

In some embodiments, the second mesa contact structure 18 includes a seventh injection part 180, a seventh extension part 181 connected to the seventh injection part 180, an eighth injection part 182 separated from the seventh extension part 181, and an eighth extension part 183 connected to the eighth injection part 182. In some embodiments, the first injection part 130 of the first mesa contact structure 13 and the seventh injection part 180 of the second mesa contact structure 18 are close to the first short side SS1 and far away from the second short side SS2. In some embodiments, the first mesa contact structure 13 is symmetrical with the second mesa contact structure 18 with respect to a center axis of the semiconductor device 5. In some embodiments, the shape, the size (e.g., length or width), and/or the material of the first mesa contact structure 13 and the second mesa contact structure 18 are the same or similar.

In some embodiments, the end of the second extension part 133 and the end of the eighth extension part 183 are bent to close to each other. More specifically, the second extension part 133 includes a first bent section 133E, the eighth extension part 183 includes a second bent section 183E, and a distance between the first bent section 133E and the second bent section 183E is smaller than a distance between the second injection part 132 and the eighth injection part 182. By virtue of the first bent section 133E and the second bent section 183E, the current of the semiconductor device 5 may be evenly dispersed.

Similar to the semiconductor device 4 shown in FIG. 5, the semiconductor device 5 in FIG. 6A also includes an insulating structure 11 having a first opening 111 to expose the first injection part 130, a second opening 112 to expose the second injection part 132, a third opening 113 to expose the third injection part 120, and a fifth opening 115 to expose the fifth injection part 170. Besides, the insulating structure 11 also includes a sixth opening 116 to expose the seventh injection part 180 and a seventh opening 117 to expose the eighth injection part 182. The first extension part 131, the second injection part 133, the third extension part 121, the fifth extension part 171, the seventh extension part 181 and the eighth extension part 183 are covered by the insulating structure 11.

FIG. 6B is a top view showing the semiconductor device 6 according to some embodiments of the present disclosure. Compared to the semiconductor device 5 of FIG. 6A, each of the first mesa contact structure 13 and the second mesa contact structure 18 is a contact structure with one extension part and one injection part rather than two extension parts and two injection parts. In other words, the second injection part 132 and the second extension part 133 of the first mesa contact structure 13 and the eighth injection part 182 and the eighth extension part 183 of the second mesa contact structure 18 are omitted.

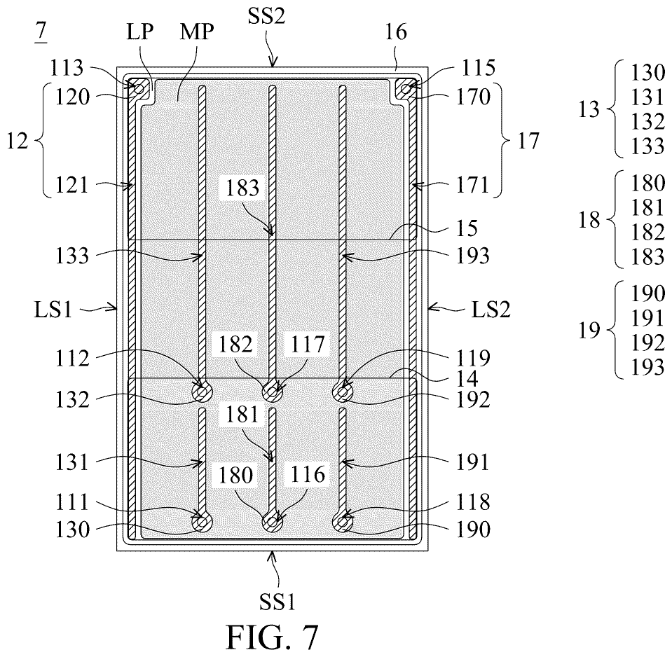

FIG. 7 is a top view showing the semiconductor device 7 according to some embodiments of the present disclosure. Compared to the semiconductor device 4 of FIG. 5, the semiconductor device 7 of FIG. 7 further includes a second mesa contact structure 18 and a third mesa contact structure 19 located on the mesa portion MP. The first mesa contact structure 13, the second mesa contact structure 18, and the third mesa contact structure 19 are between the first lower contact structure 12 and the second lower contact structure 17, wherein the first mesa contact structure 13 is close to the first long side LS1 and away from the second long side LS2, the third mesa contact structure 19 is close to the second long side LS2 and away from the first long side LS1, and the second mesa contact structure 18 is between the first mesa contact structure 13 and the third mesa contact structure 19. By providing three or more than three mesa contact structures in the semiconductor, the optoelectronic properties (such as near-field uniformity) may be further improved.

In some embodiments, the shape, the size (e.g., length or width), and/or the material of the first mesa contact structure 13, the second mesa contact structure 18, and the third mesa contact structure 19 are the same or similar.

In some embodiments, the second mesa contact structure 18 includes a seventh injection part 180, a seventh extension part 181 connected to the seventh injection part 180, an eighth injection part 182 separated from the seventh extension part 181, and an eighth extension part 183 connected to the eighth injection part 182. Besides, the third mesa contact structure 19 includes a ninth injection part 190, a ninth extension part 191 connected to the ninth injection part 190, a tenth injection part 192 separated from the ninth extension part 191, and a tenth extension part 193 connected to the tenth injection part 192. In some embodiments, the first injection part 130 of the first mesa contact structure 13, the seventh injection part 180 of the second mesa contact structure 18, and the ninth injection part 190 of the third mesa contact structure 19 are close to the first short side SS1 and far away from the second short side SS2.

Similar to the semiconductor device 5 shown in FIG. 6A, the semiconductor device 7 in FIG. 7 also includes an insulating structure 11 having a first opening 111 to expose the first injection part 130, a second opening 112 to expose the second injection part 132, a third opening 113 to expose the third injection part 120, a fifth opening 115 to expose the fifth injection part 170, a sixth opening 116 to expose the seventh injection part 180 and a seventh opening 117 to expose the eighth injection part 182. Besides, the insulating structure 11 also includes a eighth opening 118 to expose the ninth injection part 190 and a ninth opening 119 to expose the tenth injection part 192. The first extension part 131, the second injection part 133, the third extension part 121, the fifth extension part 171, the seventh extension part 181, the eighth extension part 183, ninth extension part 191 and tenth extension part 193 are covered by the insulating structure 11.

In summary, the present disclosure provides a semiconductor device, which includes the lower contact structure with two injection parts and two extension parts, the mesa contact structure with two injection parts and two extension parts, or both. By providing two injection parts, the transmission distance of the current can be significantly decreased, thereby improving the problem of uniformly emitted light. In addition, by controlling the relative position, size, number, or detailed structure of the lower contact structure and the mesa contact structure, the optoelectronic characteristics of the semiconductor device can also be adjusted to better meet the design requirements.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, having a first long side and a second long side opposite to the first long side, and comprising:
a semiconductor stack having a lower portion and a mesa portion connected to the lower portion;
a first lower contact structure on the lower portion;
a first mesa contact structure on the mesa portion and comprising:
a first injection part;
a first extension part connected to the first injection part;
a second injection part separated from the first extension part; and
a second extension part connected to the second injection part; and
a first electrode structure covering a part of the mesa portion and electrically connected to the first mesa contact structure.

2. The semiconductor device as claimed in claim 1, wherein the first extension part and/or the second extension part are parallel to the first long side.

3. The semiconductor device as claimed in claim 1, further comprising:
a second electrode structure covering a part of the lower portion and electrically connected to the first lower contact structure.

4. The semiconductor device as claimed in claim 1, wherein the first injection part comprises a first width, and the first extension part comprises a second width less than the first width.

5. The semiconductor device as claimed in claim 1, wherein the first mesa contact structure is close to the second long side and away from the first long side.

6. The semiconductor device as claimed in claim 1, wherein the first lower contact structure comprises:
a third injection part;
a third extension part connected to the third injection part;
a fourth injection part separated from the third extension part; and
a fourth extension part connected to the fourth injection part.

7. The semiconductor device as claimed in claim 6, wherein the third extension part and/or the fourth extension part are parallel to the first long side.

8. The semiconductor device as claimed in claim 1, further comprising an insulating structure covering the semiconductor stack, the first mesa contact structure, and the first lower contact structure, wherein the first injection part and the second injection part are exposed by the insulating structure.

9. The semiconductor device as claimed in claim 8, wherein the insulating structure comprises a first opening to expose the first injection part and a second opening to expose the second injection part.

10. The semiconductor device as claimed in claim 1, further comprising:
a second lower contact structure on the lower portion, wherein the second lower contact structure is close to the second long side and away from the first long side.

11. The semiconductor device as claimed in claim 10, wherein the mesa portion is between the first lower contact structure and the second lower contact structure.

12. The semiconductor device as claimed in claim 10, wherein the second lower contact structure comprises:
a fifth injection part;
a fifth extension part connected to the first injection part;
a sixth injection part separated from the first extension part; and
a sixth extension part connected to the second injection part.

13. The semiconductor device as claimed in claim 12, wherein the fifth extension part and/or the sixth extension part are parallel to the first long side.

14. The semiconductor device as claimed in claim 12, wherein the first lower contact structure is symmetrical with the second lower contact structure.

15. The semiconductor device as claimed in claim 10, further comprising:
a second mesa contact structure located on the mesa portion.

16. The semiconductor device as claimed in claim 15, wherein the first mesa contact structure and the second mesa contact structure are between the first lower contact structure and the second lower contact structure.

17. The semiconductor device as claimed in claim 15, wherein the second mesa contact structure comprises:
a seventh injection part;
a seventh extension part connected to the seventh injection part;
an eighth injection part separated from the seventh extension part; and
an eighth extension part connected to the eighth injection part.

18. The semiconductor device as claimed in claim 15, wherein the first mesa contact structure is symmetrical with the second mesa contact structure.

19. The semiconductor device as claimed in claim 17, wherein the second extension part comprises a first bent section, the eighth extension part comprises a second bent section, and a distance between the first bent section and the second bent section is smaller than a distance between the second injection part and the eighth injection part.

20. A semiconductor device comprising:
a semiconductor stack having a lower portion and a mesa portion connected to the lower portion;
a first lower contact structure on the lower portion and comprising:
a third injection part;
a third extension part connected to the first injection part;
a fourth injection part separated from the first extension part; and
a fourth extension part connected to the second injection part;
a first mesa contact structure on the mesa portion; and
a first electrode structure covering a part of the mesa portion and electrically connected to the mesa contact structure.
